(19) United States
(12) Patent Application Publication
(10) Pub. No.: US 2010/0263701 A1
(43) Pub. Date: Oct. 21, 2010

(54) THERMOELECTRIC DEVICE, MANUFACTURING METHOD FOR MANUFACTURING THERMOELECTRIC DEVICE, CONTROL SYSTEM FOR CONTROLLING THERMOELECTRIC DEVICE, AND ELECTRONIC APPLIANCE

(75) Inventors: Kazuaki Yazawa, Tokyo (JP); Yuichi Ishida, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/755,816

(22) Filed: Apr. 7, 2010

(30) Foreign Application Priority Data
Apr. 15, 2009 (JP) 2009-098547

(51) Int. Cl. H01L 35/28; H05K 13/00

(52) U.S. Cl. 136/203; 29/592.1

(57) ABSTRACT

A thermoelectric device includes rows of thermoelectric elements, each of which includes p-type thermoelectric elements and n-type thermoelectric elements that are alternately arranged in a first direction, the n-type thermoelectric elements each having a junction area electrically connected to one of the p-type thermoelectric elements that adjoins the n-type thermoelectric element; first insulators; and a second insulator. In the thermoelectric device, the first insulators are each arranged between a corresponding one of the p-type thermoelectric elements and one of the n-type thermoelectric elements that adjoins the p-type thermoelectric element. The rows of the thermoelectric elements are arranged in a second direction perpendicular to the first direction and connected to each other. The second insulator is arranged between the rows of thermoelectric elements in such a manner that the p-type thermoelectric elements and n-type thermoelectric elements of the rows of the thermoelectric elements are electrically connected in series.

### BACKGROUND OF THE INVENTION

1. Field of the Invention

The present invention relates to thermoelectric devices having a thermoelectric element, manufacturing methods for manufacturing thermoelectric devices, control systems for controlling thermoelectric devices, and electronic appliances.

2. Description of the Related Art

A thermoelectric device in which a thermoelectric element used as a Peltier cooling device is used includes a pair of insulating boards, a plurality of p-type thermoelectric elements, a plurality of n-type thermoelectric elements, and electrodes that are used to connect the p-type thermoelectric elements and the n-type thermoelectric elements. The p-type thermoelectric elements and the n-type thermoelectric elements are alternately arranged so as to be spaced apart from each other and disposed between the pair of the insulating boards. More specifically, the p-type and n-type thermoelectric elements are soldered to electrodes formed on opposing surfaces of the pair of the insulating boards, and are connected in series. When a current is supplied to the p-type and n-type thermoelectric elements from outside, one of the insulating boards becomes a board that absorbs heat and the other becomes a board that dissipates heat in accordance with the direction of the current flow (for example, see paragraphs [0022] to [0025] and FIG. 1 of Japanese Unexamined Patent Application Publication No. 2003-174202).

### SUMMARY OF THE INVENTION

In the thermoelectric device described in Japanese Unexamined Patent Application Publication No. 2003-174202, the p-type and n-type thermoelectric elements are soldered to the electrodes. Thus, the resistance at interfaces between the p-type and n-type thermoelectric elements and the electrodes may increase. Moreover, the p-type thermoelectric elements and the n-type thermoelectric elements are arranged so as to be spaced apart from each other, and thus it is difficult to cause the thermoelectric device to have a higher heat density and reduce the size of the thermoelectric device.

Moreover, when the thermoelectric device as described above is manufactured, patterning is generally performed to form electrodes on insulator layers, and p-type and n-type thermoelectric elements are each arranged (picked up and placed) on these electrodes. When this manufacturing method is employed, it is necessary to pick up and place the p-type and n-type thermoelectric elements with high accuracy, resulting in poor productivity and higher cost.

Moreover, a method for manufacturing thermoelectric devices whose size is small may employ a method for forming p-type and n-type thermoelectric elements using a thin film coating technology. However, it is difficult to obtain a temperature difference (ΔT>20° C.), which is believed to be practical for achieving a sufficient efficiency for the thermoelectric conversion. On the other hand, formation of a film whose thickness is sufficient for achieving a sufficient thermoelectric conversion efficiency takes an extremely long time, resulting in higher manufacturing cost.

It is desirable to provide a thermoelectric device whose size is small and that has a sturdy structure, reduces the contact electrical resistance between thermoelectric elements, and has a higher heat density. It is also desirable to provide a control system for controlling this thermoelectric device and an electric appliance provided with this thermoelectric device.

It is also desirable to provide a manufacturing method for manufacturing the thermoelectric device. The method keeps manufacturing cost low, makes mass production possible, and allows the size of the thermoelectric device to be selected with greater flexibility.

A thermoelectric device according to an embodiment of the present invention includes rows of thermoelectric elements, each of which includes a plurality of p-type thermoelectric elements and a plurality of n-type thermoelectric elements that are alternately arranged in a first direction, the n-type thermoelectric elements each having a junction area electrically connected to one of the p-type thermoelectric elements that adjoins the n-type thermoelectric element; first insulators; and a second insulator.

The first insulators are each arranged between a corresponding one of the p-type thermoelectric elements and one of the n-type thermoelectric elements that adjoins the p-type thermoelectric element.

The rows of the thermoelectric elements are arranged in a second direction perpendicular to the first direction and connected to each other.

The second insulator is arranged between the rows of thermoelectric elements in such a manner that the p-type thermoelectric elements and n-type thermoelectric elements of the rows of the thermoelectric elements are electrically connected in series.

According to this embodiment of the present invention, the p-type thermoelectric elements may be directly connected to the n-type thermoelectric elements at junction areas. Thus, the contact electrical resistance between the p-type thermoelectric elements and the n-type thermoelectric elements is reduced and the thermoelectric device has a higher heat density. Moreover, the p-type thermoelectric elements are insulated from the n-type thermoelectric elements by the first insulators at areas other than the junction areas. Thus, compared with a case where the p-type thermoelectric elements and the n-type thermoelectric elements are arranged so as to be spaced apart from each other in order to electrically insulate the p-type thermoelectric elements from the n-type thermoelectric elements, higher insulating properties are obtained and a small and sturdy structure is achieved.

According to a manufacturing method for manufacturing a thermoelectric device according to another embodiment of the present invention, a first layered product is obtained by alternately stacking a plurality of p-type thermoelectric elements and a plurality of n-type thermoelectric elements in a first direction and by arranging first insulators each between a corresponding one of the p-type thermoelectric elements and one of the n-type thermoelectric elements that adjoins the p-type thermoelectric element in such a manner that the p-type thermoelectric elements and the n-type thermoelectric elements are electrically connected to each other at junction areas.

According to the manufacturing method, a connected product is obtained by connecting the p-type and n-type thermoelectric elements of the first layered product to each other through pressing the first layered product while heating.

According to the manufacturing method, rows of thermoelectric elements are obtained by cutting the connected product, each of which is constituted by the p-type thermoelectric elements and the n-type thermoelectric elements that are connected to each other.

According to the manufacturing method, a second layered product is obtained by stacking the rows of the thermoelectric elements and by arranging a second insulator between the rows of thermoelectric elements in such a manner that the p-type thermoelectric elements and n-type thermoelectric elements of the rows of the thermoelectric elements are electrically connected in series.

According to the manufacturing method, the stacked rows of the thermoelectric elements of the second layer product are connected to each other through pressing the second layered product while heating.

According to this embodiment of the present invention, a thermoelectric device is manufactured mainly using simple processes such as stacking and cutting thermoelectric elements and insulators, and thus manufacturing cost is kept low compared with a case of manufacturing thermoelectric devices using a film deposition process. According to this embodiment of the present invention, furthermore, the size of the thermoelectric device is allowed to be selected with greater flexibility by selecting, as appropriate, the number of thermoelectric elements to be stacked and the number of rows of thermoelectric elements to be stacked. Thus, a thermoelectric device appropriate for the size of a heat source is easily obtained.

A control system for controlling a thermoelectric device according to another embodiment of the present invention is a control system for controlling a thermoelectric device that includes rows of thermoelectric elements, each of which includes a plurality of p-type thermoelectric elements and a plurality of n-type thermoelectric elements that are alternately arranged in a first direction, the n-type thermoelectric elements each having a junction area electrically connected to one of the p-type thermoelectric elements that adjoins the n-type thermoelectric element; first insulators; and a second insulator. In the thermoelectric device, the first insulators are each arranged between a corresponding one of the p-type thermoelectric elements and one of the n-type thermoelectric elements that adjoins the p-type thermoelectric element. The rows of the thermoelectric elements are arranged in a second direction perpendicular to the first direction and connected to each other. The second insulator is arranged between the rows of thermoelectric elements in such a manner that the p-type thermoelectric elements and n-type thermoelectric elements of the rows of the thermoelectric elements are electrically connected in series.

The control system for controlling the thermoelectric device includes an input unit that receives temperature information regarding an integrated circuit part to be cooled, and a control circuit that controls a current to be supplied to the thermoelectric device in accordance with the temperature information received by the input unit.

According to this embodiment of the present invention, the thermoelectric device may be one of thermoelectric devices to be controlled by the control system, the integrated circuit part may be one of integrated circuit parts to be cooled, and the thermoelectric devices may be arranged with respect to the integrated circuit parts.

The input unit may receive temperature information regarding each of the integrated circuit parts to be cooled.

The control circuit may individually control currents to be supplied to the thermoelectric devices in accordance with the temperature information received by the input unit.

According to this embodiment of the present invention, the currents to be supplied to the thermoelectric devices may individually be controlled in accordance with the temperature information of the integrated circuit parts to be cooled. Thus, the thermal transport properties of the thermoelectric devices are diversely controlled.

An electric appliance according to another embodiment of the present invention includes a heat source that has a package, and a thermoelectric device provided at the package of the heat source.

The thermoelectric device includes rows of thermoelectric elements, each of which includes a plurality of p-type thermoelectric elements and a plurality of n-type thermoelectric elements that are alternately arranged in a first direction, the n-type thermoelectric elements each having a junction area electrically connected to one of the p-type thermoelectric elements that adjoins the n-type thermoelectric element; first insulators; and a second insulator.

The first insulators are each arranged between a corresponding one of the p-type thermoelectric elements and one of the n-type thermoelectric elements that adjoins the p-type thermoelectric element.

The rows of the thermoelectric elements are arranged in a second direction perpendicular to the first direction and connected to each other.

The second insulator is arranged between the rows of thermoelectric elements in such a manner that the p-type thermoelectric elements and n-type thermoelectric elements of the rows of the thermoelectric elements are electrically connected in series.

According to this embodiment of the present invention, the p-type thermoelectric elements are electrically connected to the n-type thermoelectric elements at junction areas of the p-type and n-type thermoelectric elements. The p-type and n-type thermoelectric elements are connected to each other without arranging electrodes therebetween, and thus the contact electrical resistance between the p-type thermoelectric elements and the n-type thermoelectric elements is reduced and a higher heat density is achieved. Since the first insulators are arranged between the p-type thermoelectric elements and the n-type thermoelectric elements, spaces between the p-type thermoelectric elements and the n-type thermoelectric elements are not necessary to spatially insulate the p-type thermoelectric elements from the n-type thermoelectric elements. Thus, a small and sturdy structure is achieved. Since this thermoelectric device is made compact, the thermoelectric device can be locally arranged at the heat source. Moreover, since the thermoelectric device has a higher heat density, heat released from this heat source is efficiently absorbed.

According to the thermoelectric device according to the embodiments of the present invention, a thermoelectric device is realized whose contact electrical resistance between thermoelectric elements is reduced and that has a higher heat density and a small and sturdy structure. Moreover, according to the embodiments of the present invention, a control system for controlling the thermoelectric device and an electric appliance including the thermoelectric device are provided.

According to the manufacturing method for manufacturing the thermoelectric device, manufacturing cost is kept low, mass production is made possible, and the size of the thermoelectric device is allowed to be selected with greater flexibility.

### BRIEF DESCRIPTION OF THE DRAWINGS

FIG. 1 is a side view of a thermoelectric device according to an embodiment of the present invention;

FIG. 2 is a plan view of the thermoelectric device;

FIG. 3 is a perspective view of the thermoelectric device;

FIG. 4 is a flowchart showing a method for manufacturing the thermoelectric device;

FIG. 5 is a partially sectional view of a layered product;

FIG. 6 is a plan view of the layered product;

FIG. 7 is a partially enlarged plan view of the layered product;

FIG. 8 is a perspective view of a bulk;

FIG. 9 is a perspective view of rows of thermoelectric elements cut from the bulk;

FIG. 10 is an exploded perspective view of stacked rows of thermoelectric elements with second insulators between parts thereof;

FIG. 11 is a sectional view showing an embodiment in which the thermoelectric device is mounted on an integrated circuit (IC) part;

FIG. 12 is a partially enlarged sectional view showing the embodiment in which the thermoelectric device is mounted on the IC part;

FIG. 13 is diagram of the structure of a first control system that controls the thermoelectric device;

FIG. 14 is a diagram of the structure of a second control system that controls the thermoelectric device;

FIG. 15 is a sectional view showing a modified example of the embodiment in which the thermoelectric device is mounted on the IC part, which is to be cooled;

FIG. 16 is a diagram showing a modified example of the structure of the second control system that controls the thermoelectric device;

FIG. 17 is a diagram of the structure of a third control system that controls the thermoelectric device;

FIG. 18 is a side view of a desktop personal computer (PC) as an electronic appliance provided with the thermoelectric device; and

FIG. 19 is a perspective view showing a modified example of the thermoelectric device.

### DESCRIPTION OF THE PREFERRED EMBODIMENTS

The following will describe embodiments of the present invention with reference to the drawings.

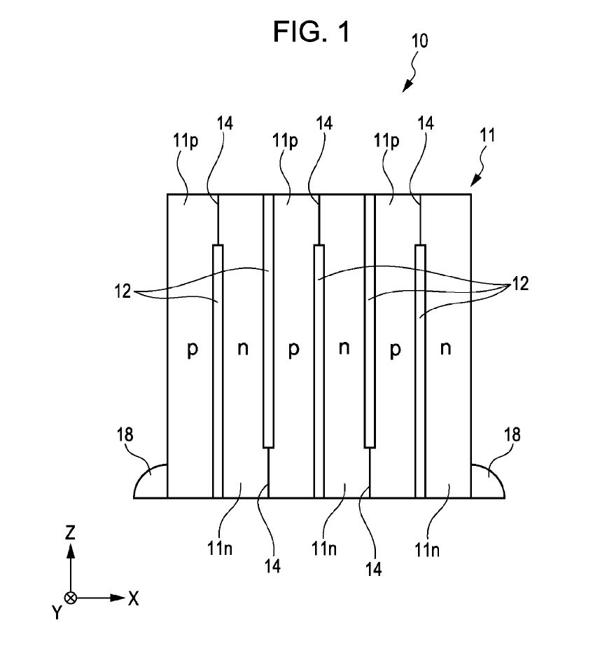

FIG. 1 is a side view of a thermoelectric device 10 according to an embodiment of the present invention.

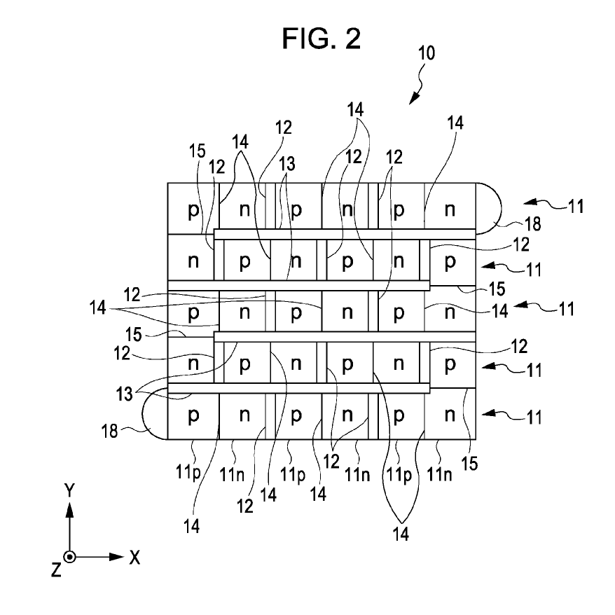

The thermoelectric device 10 has substantially a rectangular parallelepiped shape or a cube shape. The thermoelectric device 10 includes a plurality of p-type thermoelectric elements 11p, a plurality of n-type thermoelectric elements 11n, a plurality of first insulators 12, and a plurality of second insulators 13 (shown in FIG. 2 and the like).

As shown in FIG. 1, the p-type thermoelectric elements 11p and the n-type thermoelectric elements 11n, which are provided in an equal number to the p-type thermoelectric elements 11p, are alternately arranged in the direction of the x-axis. For each of the three axes, the size of the p-type thermoelectric elements 11p and the size of the n-type thermoelectric elements 11n are from about 1 μm to about 500 μm. The p-type thermoelectric elements 11p and the n-type thermoelectric elements 11n are composed of, for example, bismuth telluride (Bi₂Te₃), bismuth antimony telluride (BiSbTe), or the like.

The first insulators 12 are each arranged between a corresponding one of the p-type thermoelectric elements 11p and one of n-type thermoelectric elements 11n that adjoins the p-type thermoelectric element 11p in the direction of the x-axis. The first insulators 12 are, for example, thin films composed of silicon dioxide (SiO₂) or the like. Each of the p-type thermoelectric elements 11p and one of the n-type thermoelectric elements 11n that adjoins the p-type thermoelectric element 11p in the direction of the x-axis sandwich between parts thereof a corresponding one of the first insulators 12 and are connected to each other. More specifically, each of the p-type thermoelectric elements 11p and one of the n-type thermoelectric elements 11n that adjoins the p-type thermoelectric element 11p in the direction of the x-axis sandwich a corresponding one of the first insulators 12 over the entirety thereof except for a first pn junction area 14, and are connected to each other at the first pn junction area 14. First pn junction areas 14 are provided at either end of the p-type thermoelectric elements 11p and the n-type thermoelectric elements 11n in the direction of z-axis to form pi junctions. More specifically, regarding the first pn junction areas 14 that are adjoined in the direction of the x-axis, one of the first pn junction areas 14 is provided at one end of one of the p-type thermoelectric elements 11p and the n-type thermoelectric elements 11n in the direction of the z-axis and an adjoining one of the first pn junction areas 14 is provided at the other end of the p-type thermoelectric elements 11p and the n-type thermoelectric elements 11n in the direction of the z-axis. A structure in which the p-type thermoelectric elements 11p and the n-type thermoelectric elements 11n are alternately arranged and connected to each other in the direction of the x-axis as described above is called a “thermoelectric element row 11”, which is a row of thermoelectric elements.

The thermoelectric device 10 is formed by alternately arranging and stacking the thermoelectric element rows 11 and second insulators 13 in the direction of the y-axis in such a manner that adjoining thermoelectric element rows 11 sandwich between parts thereof a corresponding one of the second insulators 13 and connecting the thermoelectric element rows 11 to each other.

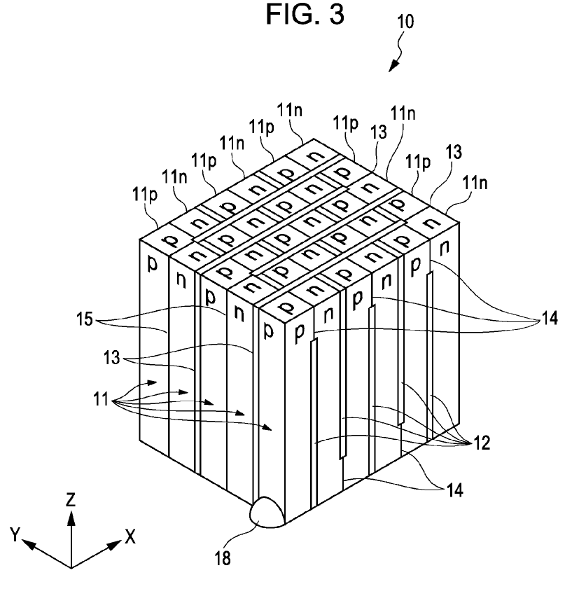

FIG. 2 is a plan view of the thermoelectric device 10. FIG. 3 is a perspective view of the thermoelectric device 10.

As shown in FIGS. 2 and 3, the p-type thermoelectric elements 11p and the n-type thermoelectric elements 11n of the thermoelectric element rows 11 that are adjoined in the direction of the y-axis are arranged to form a checkerboard pattern. The second insulators 13 are arranged to electrically insulate the entirety of the thermoelectric element rows 11 from each other except for second pn junction areas 15 in such a manner that a p-type thermoelectric element 11p located at either end of each of the thermoelectric element rows 11 is directly connected to an n-type thermoelectric element 11n located at the same end of an adjoining one of the thermoelectric element rows 11 so as to form a second pn junction area 15. That is, the thermoelectric element rows 11 that are adjoined in the direction of the y-axis sandwich the second insulators 13 over the entirety thereof except for the second pn junction areas 15, and are connected to each other at the second pn junction areas 15. Regarding the second pn junction areas 15 that are adjoined in the direction of the y-axis, one of the second pn junction areas 15 is provided at one end of one of the p-type thermoelectric elements 11p and n-type thermoelectric elements 11n in the direction of the x-axis and an adjoining one of the second pn junction areas 15 is provided at the other end of an adjoining one of the p-type thermoelectric elements 11p and n-type thermoelectric elements 11n in the direction of the x-axis.

As a result, all of the p-type thermoelectric elements 11p and n-type thermoelectric elements 11n of the thermoelectric element rows 11 are electrically connected in series in the thermoelectric device 10. Reference numeral 18 denotes an extraction electrode for feeding a current to the thermoelectric device 10. The thermoelectric device 10 has extraction electrodes 18 for a p-type thermoelectric element 11p and an n-type thermoelectric element 11n that are arranged on a diagonal of a plane formed by the x-axis and the y-axis; the p-type thermoelectric element 11p is provided with one of the extraction electrodes 18 and the n-type thermoelectric element 11n is provided with one of the extraction electrodes 18.

The thermoelectric device 10 has been described in which five thermoelectric element rows 11, in each of which three p-type thermoelectric elements 11p and three n-type thermoelectric elements 11n are alternately arranged in the direction of the x-axis, are arranged and connected to each other in the direction of the y-axis. However, embodiments of the present invention are not limited thereto. The thermoelectric element row 11 may be a thermoelectric element row in which two p-type thermoelectric elements 11p and two n-type thermoelectric elements 11n at least are alternately arranged in the direction of the x-axis. The thermoelectric device 10 may be a thermoelectric device that has two or more thermoelectric element rows 11 arranged.

According to the thermoelectric device 10 in this embodiment, the p-type thermoelectric elements 11p are directly connected to the n-type thermoelectric elements 11n at the first pn junction areas 14 and the second pn junction areas 15 and form pn junctions in the thermoelectric element rows 11. Thus, the thermoelectric device 10 has a structure that makes it hard to cause a vena contracta at a surface where a current flows. The structure can significantly reduce a contact electrical resistance (an internal resistance) and the thermoelectric device 10 can have a higher heat density, and thus device characteristics similar to element characteristics can be realized. Moreover, since the thermoelectric device 10 does not have clearance inside, the thermoelectric device 10 can be more compact and a more sturdy structure can be realized for the thermoelectric device 10.

Next, a method for manufacturing the thermoelectric device 10 having the above-described structure will be described.

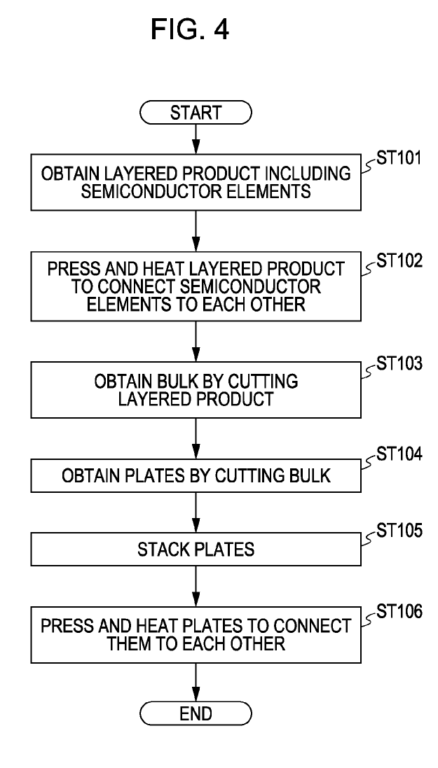

FIG. 4 is a flowchart showing a method for manufacturing the thermoelectric device 10.

First, the p-type thermoelectric elements 11p and the n-type thermoelectric elements 11n, which are provided in an equal number to the p-type thermoelectric elements 11p, are prepared. The p-type thermoelectric elements 11p and n-type thermoelectric elements 11n are wafer-like or sheetlike. In step ST101, a layered product 20 is obtained by alternately stacking these p-type thermoelectric elements 11p and n-type thermoelectric elements 11n and arranging the first insulators 12, which are long and sheetlike, each between a corresponding one of the p-type thermoelectric elements 11p and one of the n-type thermoelectric elements 11n that adjoins the p-type thermoelectric element 11p. The first insulators 12 are made of, for example, SiO₂.

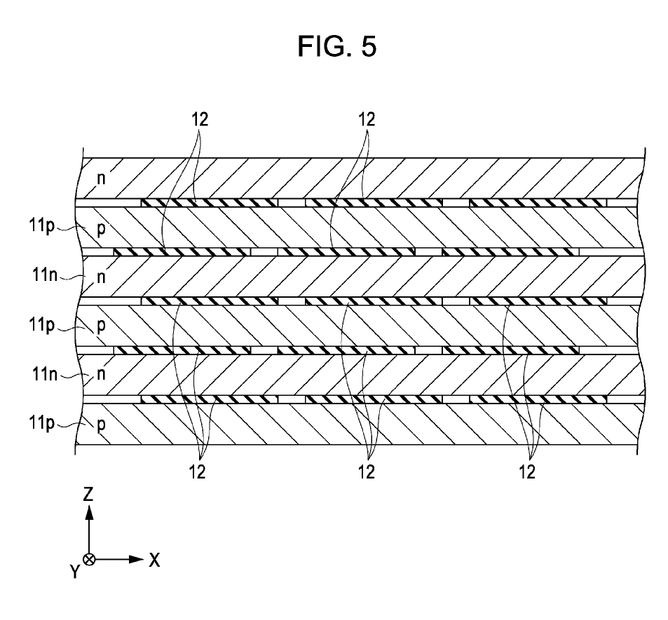

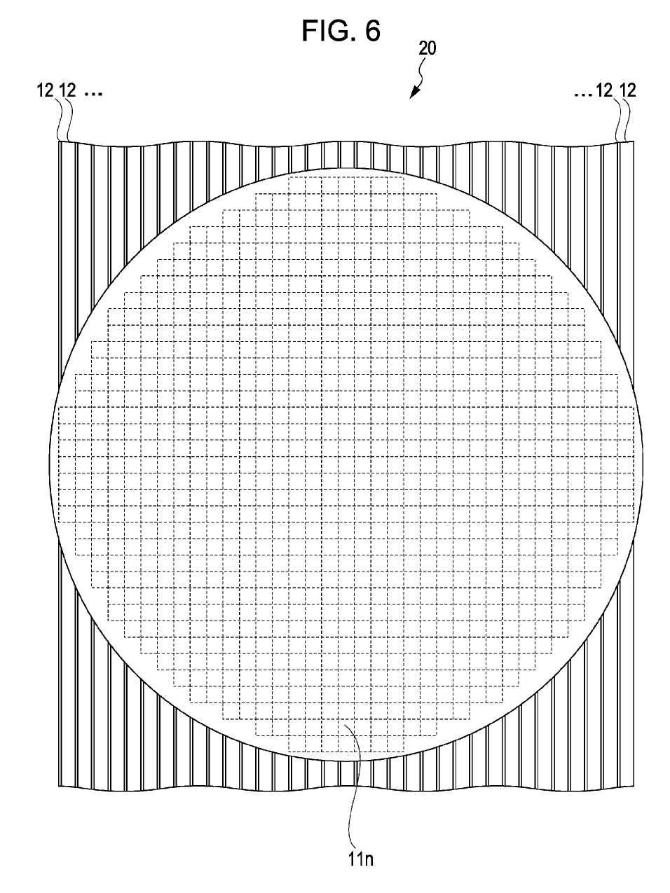

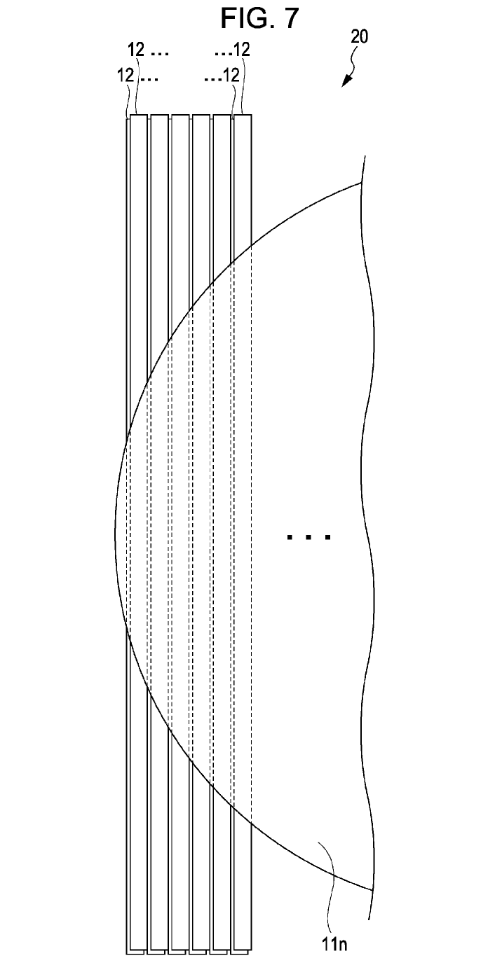

FIG. 5 is a partially sectional view of the layered product 20. FIG. 6 is a plan view of the layered product 20. FIG. 7 is a partially enlarged plan view of the layered product 20.

As shown in FIGS. 5, 6, and 7, first insulators 12 are arranged between a layer of a p-type thermoelectric element 11p and a layer of an n-type thermoelectric element 11n in the layered product 20. The first insulators 12 are arranged parallel to each other with a predetermined spacing therebetween in the direction that is perpendicular to the direction in which the layers are stacked (the direction that is perpendicular to the lengthwise direction of the first insulators 12). Here, first insulators 12 that are adjacent to one another in the direction in which the layers are stacked are staggered in the direction that is perpendicular to the direction in which the layers are stacked and the lengthwise direction of the first insulators 12.

Each layer of a p-type thermoelectric element 11p and an n-type thermoelectric element 11n may be formed of a granular material instead of the above-described wafer-like or sheetlike layers. Moreover, instead of the method for stacking the first insulators 12, which are sheetlike, a method for obtaining thin-film-like first insulators 12 in advance by performing a predetermined patterning method on surfaces of the p-type thermoelectric elements 11p and the n-type thermoelectric elements 11n may be utilized. Here, a conductive film, which is not shown, for increasing strength of electrical and mechanical connection between layers may be formed in areas where the first insulators 12 are not present between the p-type thermoelectric elements 11p and the n-type thermoelectric elements 11n (the first pn junction areas 14).

For example, Bi₂Te₃, BiSbTe, or the like may be used to form the p-type thermoelectric elements 11p and the n-type thermoelectric elements 11n.

Moreover, a material obtained by coating fine particles of Bi₂Te₃ with a nano-thin layer of antimony telluride (Sb₂Te₃) may be used to form the p-type thermoelectric elements 11p and the n-type thermoelectric elements 11n. Alternatively, a material obtained by causing phonon scattering using a fine structure obtained by mixing Bi₂Te₃, BiSbTe, or the like with nanoparticles can be used to form the p-type thermoelectric elements 11p and the n-type thermoelectric elements 11n. These thermoelectric materials reduce thermal conductivity. The p-type thermoelectric elements 11p and the n-type thermoelectric elements 11n having a low thermal conductivity are obtained by employing these thermoelectric materials for the thermoelectric device 10 according to the embodiment, whereby improving the figure of merit of the thermoelectric device 10.

In step ST102, the layered product 20 is pressed while being heated, and the p-type thermoelectric elements 11p are connected to the n-type thermoelectric elements 11n at the first pn junction areas 14 while the p-type thermoelectric elements 11p and the n-type thermoelectric elements 11n sandwich first insulators 12 between parts thereof. The layered product 20 should be heated at around 400° C. to around 500° C. for about an hour and should be pressed at around 20 MPa.

In step ST103, bulks 21, each of which has substantially a rectangular parallelepiped shape, of a desired size are obtained by cutting the layered product 20 along broken lines shown in FIGS. 5 and 6.

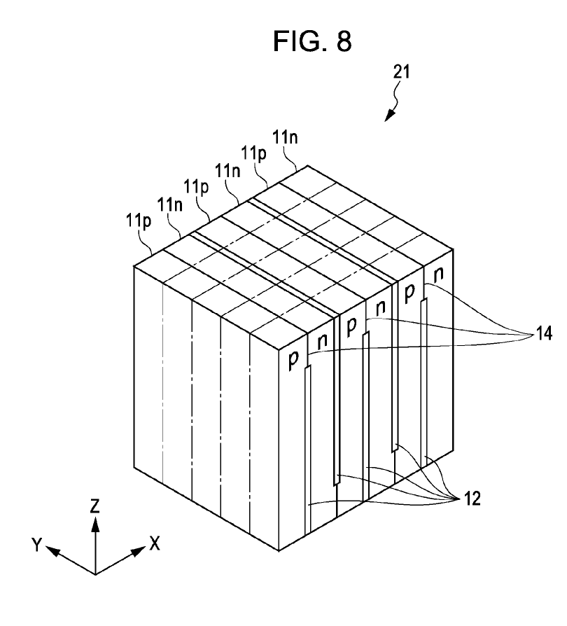

FIG. 8 is a perspective view of a cut bulk 21.

Here, the direction in which the p-type thermoelectric elements 11p and the n-type thermoelectric elements 11n are stacked is indicated by the x-axis in FIG. 8.

In the bulk 21, each of the p-type thermoelectric elements 11p and one of the n-type thermoelectric elements 11n that adjoins the p-type thermoelectric element 11p are partially insulated from each other by one of the first insulators 12 in such a manner that the first pn junction areas 14 are formed alternately at one end or the other end of the p-type thermoelectric elements 11p and n-type thermoelectric elements 11n in the direction (the direction of the z-axis in FIG. 8) that is perpendicular to the direction in which layers are stacked (the direction of the x-axis).

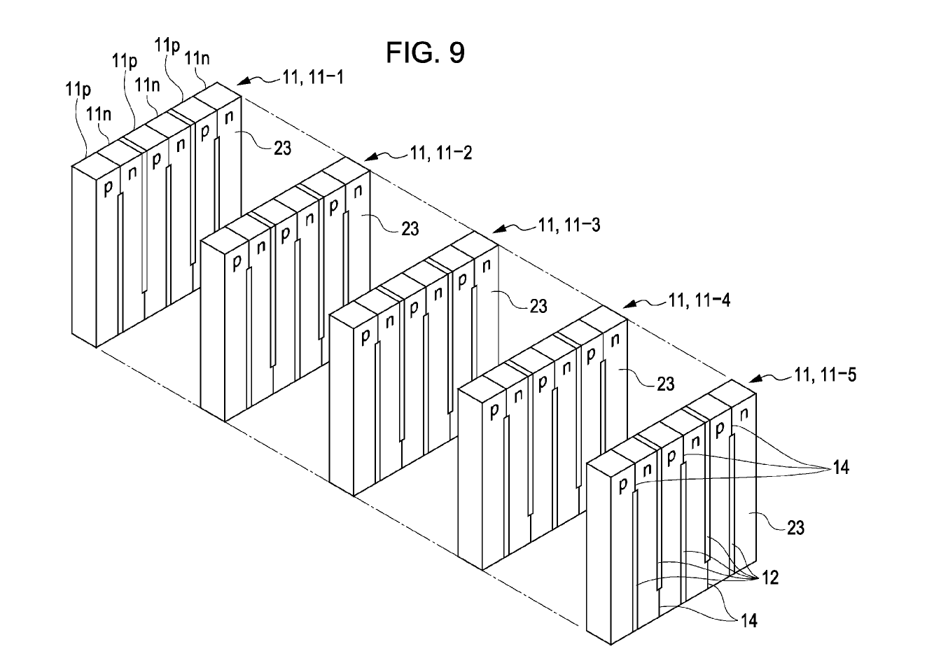

In step ST104, the bulk 21 is cut along cross sections formed by the y-axis and the z-axis perpendicular to the x-axis, the direction of which is the direction in which the p-type thermoelectric elements 11p and the n-type thermoelectric elements 11n are stacked, the sections being indicated by alternate-long-and-short-dash lines. As a result, for example, a plurality of thermoelectric element rows 11 are obtained as shown in FIG. 9.

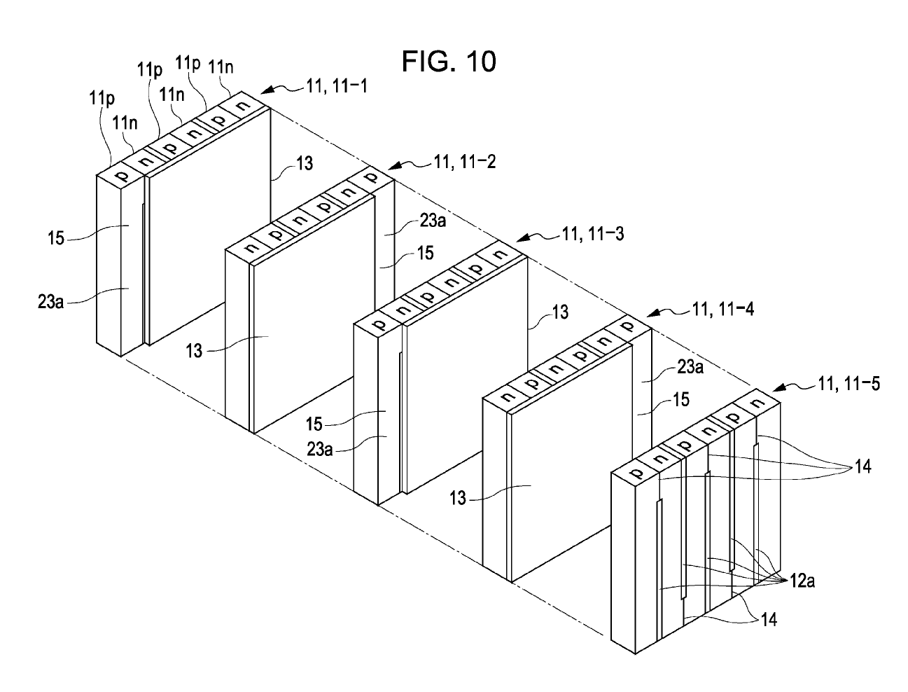

Then, for each of the thermoelectric element rows 11, a second insulator 13 is formed over the entirety of one of cross sections 23 of the thermoelectric element row 11 except for the area of a p-type thermoelectric element 11p located at one end of the thermoelectric element row 11. The second insulator 13 is formed by, for example, a predetermined patterning method. In step ST105, a plurality of the thermoelectric element rows 11 on which such a second insulator 13 is formed are stacked so as to have the second insulator 13 therebetween. In an example shown in FIG. 10, the thermoelectric element rows 11 are stacked after two thermoelectric element rows denoted by 11-2 and 11-4 have been turned by 180 degrees about the y-axis. As a result, a p-type thermoelectric element 11p located at either end of each of the thermoelectric element rows 11 faces an n-type thermoelectric element 11n located at the same end of an adjoining one of the thermoelectric element rows 11, and the remaining areas of the adjoining thermoelectric element rows 11 are insulated from each other by the second insulator 13 between the adjoining thermoelectric element rows 11.

In step ST106, the stacked thermoelectric element rows 11 are pressed while being heated, and the thermoelectric element rows 11 are connected to each other while the thermoelectric element rows 11 sandwich the second insulators 13 between parts thereof. The thermoelectric element rows 11 should be heated at around 400° C. to around 500° C. for about an hour and should be pressed at around 20 MPa. As a result, the p-type thermoelectric element 11p and the n-type thermoelectric element 11n facing to each other are connected to form the second pn junction area 15. In this way, the thermoelectric device 10 is obtained in which a plurality of p-type thermoelectric elements 11p and a plurality of n-type thermoelectric elements 11n included in the stacked thermoelectric element rows 11 are connected in series by forming pn junctions.

Here, for each of the thermoelectric element rows 11, a conductive film, which is not shown, may be formed on a surface of the thermoelectric element row 11 where the second insulator 13 is not formed, and a p-type thermoelectric element 11p and a n-type thermoelectric element 11n of adjoining thermoelectric element rows 11 may be connected to each other with the conductive film therebetween. The conductive film arranged between layers of the p-type thermoelectric element 11p and the n-type thermoelectric element 11n increases strength of electrical and mechanical connection between the layers.

Moreover, the above-described example describes, for each of the thermoelectric element rows 11, the second insulator 13 formed over the entirety of one of cross sections 23a of the thermoelectric element row 11 except for the area of a p-type thermoelectric element 11p located at one end of the cross section 23a. However, embodiments of the present invention are not limited thereto. For each of the thermoelectric element rows 11, the second insulator 13 may be formed over the entirety of one of the cross sections 23 of the thermoelectric element row 11 except for the area of an n-type thermoelectric element 11n located at one end of the cross section 23.

According to the method for manufacturing the thermoelectric device according to this embodiment, the size of the thermoelectric device 10 is allowed to be selected with a high degree of flexibility by selecting, as appropriate, the number of thermoelectric elements to be stacked and the number of thermoelectric element rows to be stacked. Thus, the thermoelectric device 10 can be designed easily to have an appropriate size for the size of a heat source. Moreover, according to the method for manufacturing the thermoelectric device according to this embodiment, the thermoelectric device 10 can be obtained mainly through simple processes including stacking and cutting layers of thermoelectric elements. Thus, the cost of manufacturing the thermoelectric device 10 is kept low and mass production is made possible, compared with a case in which thermoelectric devices are manufactured using a film deposition process.

The following describes mounting of the thermoelectric device 10 manufactured as described above on a part to be cooled.

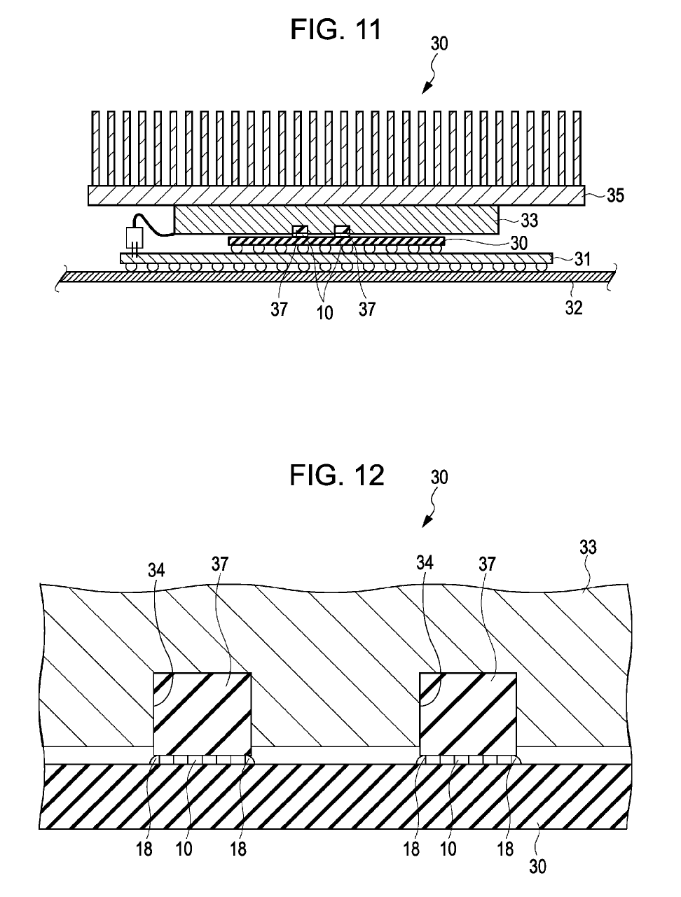

FIG. 11 is a sectional view showing an embodiment in which the thermoelectric device 10 is mounted on an IC part 30, which is to be cooled. FIG. 12 is a partially enlarged sectional view showing the embodiment in which the thermoelectric device 10 is mounted on the IC part 30.

In FIGS. 11 and 12, the IC part 30, which is to be cooled, is flip chip attached to a module board 31. The module board 31 is flip chip attached to a main board 32.

A thermal diffusion plate 33 is connected to one of the main surfaces of the IC part 30, which is to be cooled, with a layer of a thermal interface material (not shown) therebetween. The thermal diffusion plate 33 decreases the heat density of heat radiated from the IC part 30, and conducts the heat to a heat dissipating element such as a heat sink 35. The thermal diffusion plate 33 is composed of a material having a high thermal conductivity such as copper (Cu), silicon carbide (SiC), or aluminum nitride (AlN).

In this embodiment, the IC part 30, which is to be cooled, has two high heat parts (not shown) called hot spots and spaced apart from each other. Each of the high heat parts has the thermoelectric device 10 arranged at a position corresponding to the high heat part. The heat sink 35 is connected to the surface of the thermal diffusion plate 33 opposite the surface of the thermal diffusion plate 33 to which the IC part 30 is connected, with a layer of a thermal interface material (not shown) therebetween. The heat sink 35 is composed of, for example, Cu or aluminum (Al).

Here, the thermoelectric device 10 is embedded in one recess 34 or the thermoelectric devices 10 are embedded in two or more recesses 34 formed in part of the thermal diffusion plate 33 facing one of the main surfaces of the IC part 30. More specifically, for each of the thermoelectric devices 10, the entirety of the thermoelectric device 10 is covered with an insulator connection layer 37 except for the surfaces provided with the extraction electrodes 18. The insulator connection layer 37 insulates the p-type thermoelectric elements 11p and the n-type thermoelectric elements 11n of the thermoelectric device 10 from the thermal diffusion plate 33. The insulator connection layer 37 is used to bridge a gap between various members. The insulator connection layer 37 can be a thin layer and is composed of a ceramic material such as SiC or AlN. The thermoelectric device 10 is embedded in the recess 34 of the thermal diffusion plate 33 in such a manner that the surface of the thermoelectric device 10 on which the insulator connection layer 37 is not formed protrudes from the surface of the thermal diffusion plate 33 facing one of the main surfaces of the IC part 30 by about 1 μm to about 5 μm. More specifically, the thermoelectric device 10 is embedded in the recess 34 in such a manner that the insulator connection layer 37 formed on the surface of the thermoelectric device 10 closely adheres to all the internal walls of the recess 34.

The extraction electrode 18 of the thermoelectric device 10 embedded as described above is connected via a flexible cable 38 or the like to a connector 39 of a power supply 45 provided on the module board 31. This wiring is designed with consideration of changes in the distance between the module board 31 and the thermal diffusion plate 33 due to thermal expansion or the like.

Depending on the electrical insulating properties of a contact surface of a part to be cooled or the desired flatness, a flat surface may be formed by performing chemical mechanical polishing (CMP) or the like on the surface of the thermoelectric device 10 instead of forming the insulator connection layer 37, which can be used to bridge a gap. That is, if the IC part 30, which is to be cooled, is insulative, the thermoelectric device 10 may be directly contacted to the IC part 30, which is to be cooled.

According to mounting of the thermoelectric device 10 according to this embodiment, since the thermoelectric device 10 is made smaller, the thermoelectric device 10 can be locally arranged at a high heat part called a hot spot. Thus, the thermoelectric device 10 can absorb heat intensively from the hot spot to perform heat pumping.

As described above, heat pumping is performed only for the hot spot, and thus the temperature of the hot spot can be closer to the representative temperature (the average temperature in general) of the entire IC part 30, which is a part to be cooled. Thus, it is not necessary to significantly lower the temperature of the hot spot, and the structure that consumes less power and dissipates heat effectively can be made.

Here, the thermoelectric device 10 is designed to cool parts having a temperature range, for example, from room temperature to about 200° C. More specifically, the temperature range is a temperature range whose main temperature range is from room temperature to about 200° C.

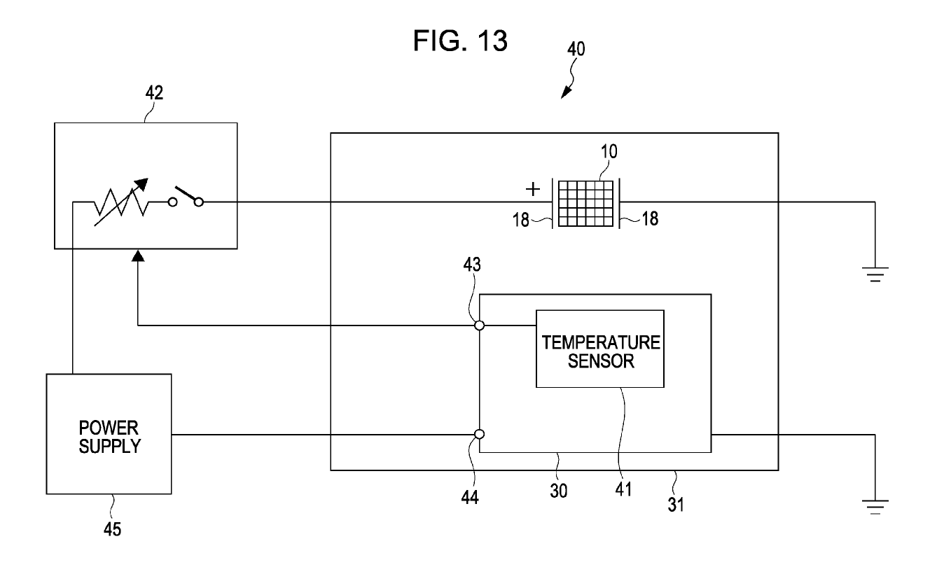

FIG. 13 is a diagram of the structure of a first control system 40 that controls the thermoelectric device 10. As shown in FIG. 13, the first control system 40 includes a temperature sensor 41, the power supply 45, and a control circuit 42.

The temperature sensor 41 is formed by, for example, a diode, a transistor, a thermistor, or the like built in the IC part 30, which is to be cooled. In general, such a temperature sensor 41 is included in a general-purpose central processing unit (CPU), a very large scale integration (VLSI), and the like so as to comply with certain specifications.

The power supply 45 applies a driving voltage to the IC part 30 via a power-supply input terminal 44 of the IC part 30, and supplies a current for driving the thermoelectric device 10 to the control circuit 42.

The control circuit 42 controls a current to be supplied to the thermoelectric device 10 via the extraction electrode 18 of the thermoelectric device 10. The control circuit 42 receives a temperature signal from a temperature-signal output terminal 43 of the IC part 30. The control circuit 42 controls the value of a current to be supplied to the thermoelectric device 10 and controls turning on/off of the current in accordance with this temperature signal. Here, in this first control system 40, the extraction electrode 18 with which a p-type thermoelectric element 11p is provided and the extraction electrode 18 with which an n-type thermoelectric element 11n is provided should be used from among the extraction electrodes 18 with which the thermoelectric device 10 is provided. For example, the extraction electrodes 18 of the p-type thermoelectric element 11p and n-type thermoelectric element 11n located at both ends of the p-type thermoelectric elements 11p and n-type thermoelectric elements 11n connected in series by pn junctions may be used.

The thermal transport properties of the thermoelectric device 10 can be controlled using the first control system 40 having the above-described structure in accordance with the temperature of the IC part 30, which is to be cooled.

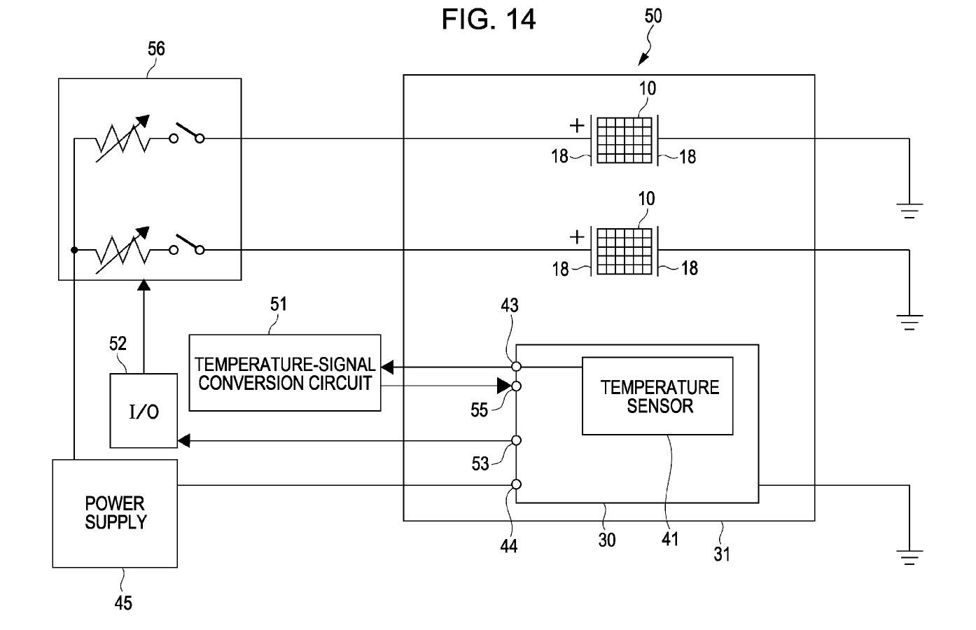

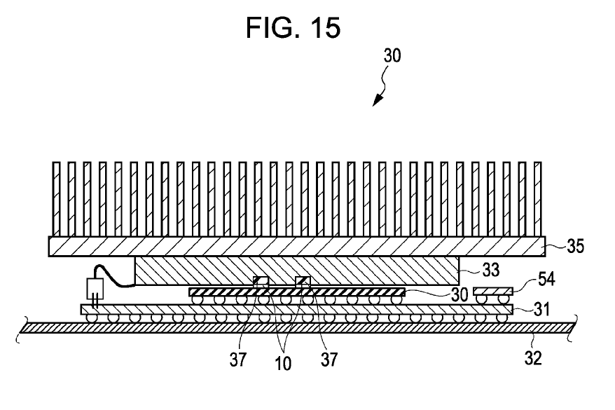

FIG. 14 is a diagram of the structure of a second control system 50 that controls the thermoelectric device 10.

The second control system 50 is a system in which the thermoelectric devices 10 shown in FIG. 11 are used.

As shown in FIG. 14, the second control system 50 includes the temperature sensor 41, the power supply 45, a control circuit 56, a temperature-signal conversion circuit 51, and an input/output (I/O) circuit 52.

The temperature sensor 41 is a sensor included in the IC part 30.

The temperature-signal conversion circuit 51 receives a temperature signal from the temperature-signal output terminal 43 of the IC part 30, converts the received temperature signal into temperature data of a predetermined format, and sends the temperature data to the IC part 30 via a temperature-data input terminal 55 of the IC part 30.

The IC part 30 stores a program for converting the temperature data acquired from the temperature-signal conversion circuit 51 into temperature data for the I/O circuit 52. The IC part 30 converts the temperature data acquired from the temperature-signal conversion circuit 51 into the temperature data for the I/O circuit 52 using this program, and outputs the temperature data for the I/O circuit 52 to the I/O circuit 52 via an output terminal 53 of the IC part 30.

The I/O circuit 52 receives the temperature data for the I/O circuit 52 from the output terminal 53 of the IC part 30, and generates and outputs a control signal for the control circuit 56.

The power supply 45 applies a driving voltage to the IC part 30 via the power-supply input terminal 44 of the IC part 30, and supplies a current for driving the thermoelectric devices 10 to the control circuit 56.

The control circuit 56 controls currents to be supplied to the two thermoelectric devices 10 via the extraction electrodes 18 of these thermoelectric devices 10. The control circuit 56 controls the values of the currents to be supplied to the two thermoelectric devices 10 and controls turning on/off of the currents to the two thermoelectric devices 10 in accordance with the control signal input from the I/O circuit 52.

The thermal transport properties of the two thermoelectric devices 10 can be controlled using the second control system 50 having the above-described structure in accordance with the positions and the temperatures of hot spots in the IC part 30, which is to be cooled.

Here, the second control system 50 can be applied to a case where one thermoelectric device 10 is to be controlled. Likewise, the control circuit 42 in the first control system 40 may be configured to control two thermoelectric devices 10.

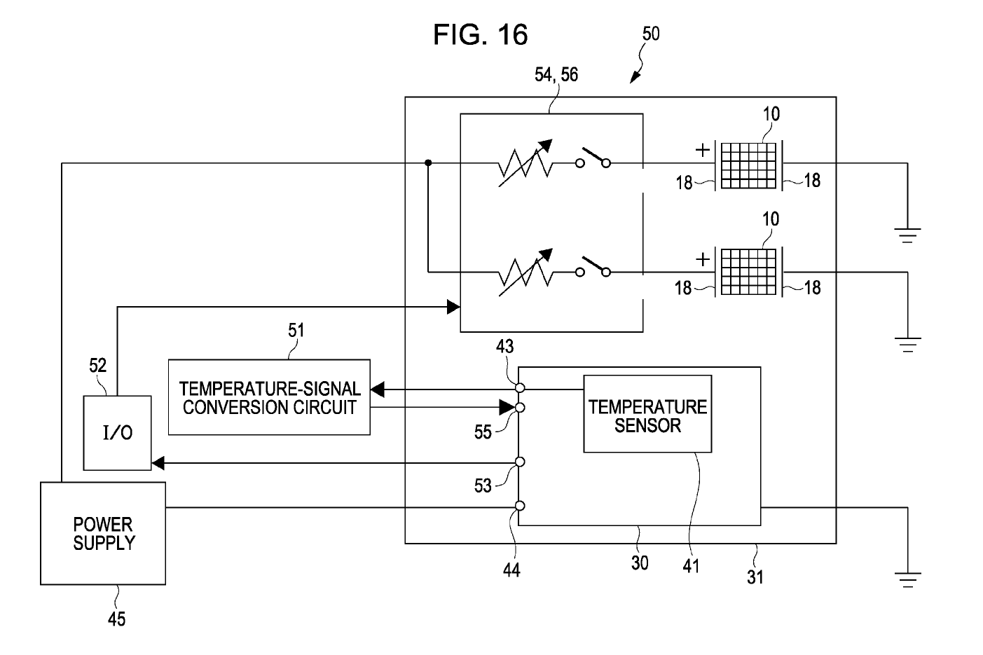

Moreover, as shown in FIGS. 15 and 16, the control circuit 56 in the second control system 50 may be incorporated as an IC part 54 mounted on the module board 31.

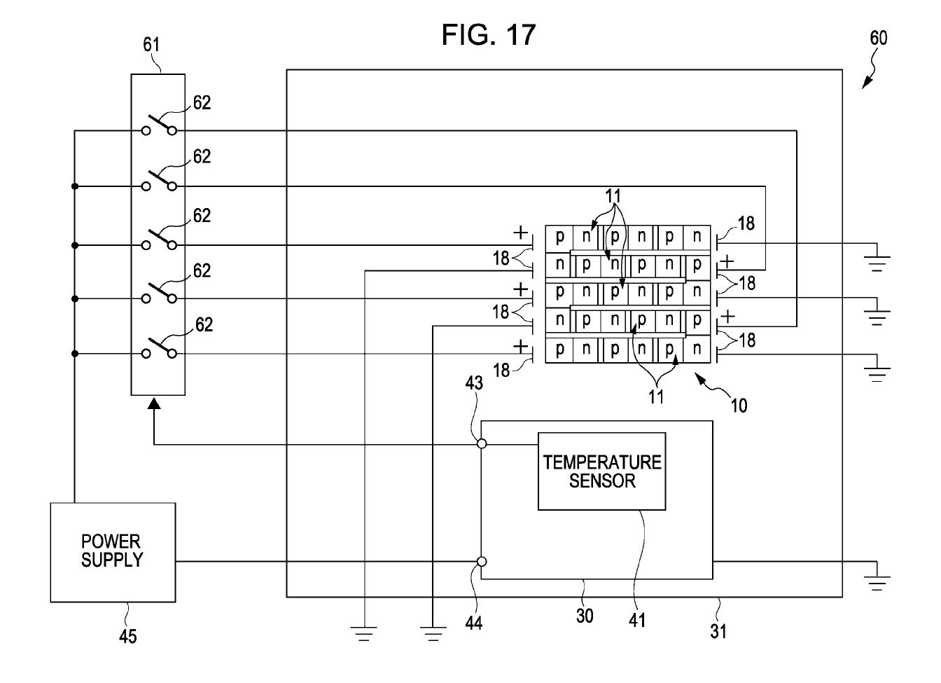

FIG. 17 is a diagram of the structure of a third control system 60 that controls the thermoelectric device 10.

As shown in FIG. 17, the third control system 60 includes the temperature sensor 41, the power supply 45, and a control circuit 61.

The temperature sensor 41 is a sensor included in the IC part 30.

The power supply 45 applies a driving voltage to the IC part 30 via the power-supply input terminal 44 of the IC part 30, and supplies a current for driving the thermoelectric device 10 to the control circuit 61.

The control circuit 61 controls currents to be supplied to the thermoelectric device 10 via the extraction electrodes 18 of the thermoelectric device 10. The control circuit 61 receives a temperature signal from the temperature-signal output terminal 43 of the IC part 30, and controls turning on/off of the currents to the thermoelectric device 10 in accordance with this temperature signal.

More specifically, the control circuit 61 includes a plurality of changeover switches 62. The changeover switches 62 in parallel with each other are each connected to a corresponding one of the extraction electrodes 18 provided at both ends of the thermoelectric element rows 11 of the thermoelectric device 10.

The third control system 60 having the above-described structure can control turning on/off of power to the thermoelectric element rows 11 in parallel by switching on/off the changeover switches 62 in accordance with the temperature of the IC part 30, which is to be cooled. Thus, the thermal transport properties of the thermoelectric device 10 can be diversely controlled using the third control system 60.

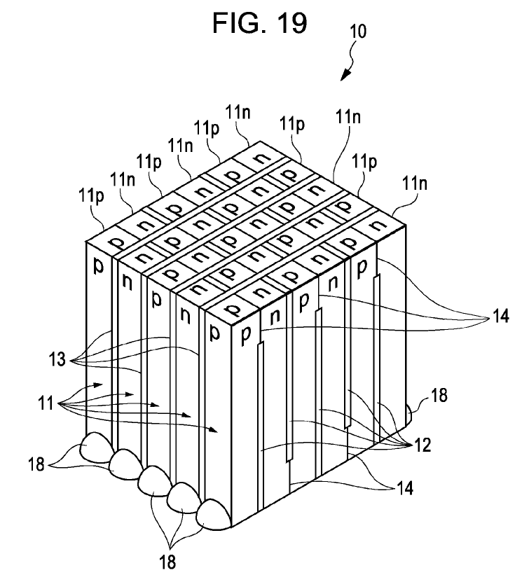

Here, when the above-described parallel control is performed, a thermoelectric device 10a shown in FIG. 19 and having a structure in which the thermoelectric element rows 11 are completely insulated from each other by the second insulators 13 may be used instead of the thermoelectric device 10.

Moreover, the third control system 60 can be applied to a case where two or more thermoelectric devices 10 are to be controlled, or to the second control system 50. Moreover, each of the thermoelectric element rows 11 is connected to one of the changeover switches 62 of the control circuit 61 in the third control system 60; however, embodiments of the present invention are not limited thereto. For example, if each of the p-type thermoelectric elements 11p and n-type thermoelectric elements 11n is connected to a corresponding one of power supplies that are arranged in a matrix, part of the p-type thermoelectric elements 11p and part of the n-type thermoelectric elements 11n can be powered in the thermoelectric element rows 11. Thus, the thermoelectric device 10 can be more diversely controlled.

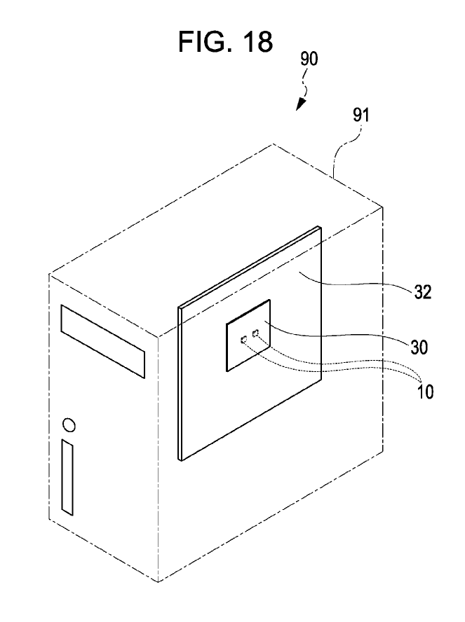

FIG. 18 is a side view of a desktop PC as an electronic appliance provided with the thermoelectric devices 10.

The IC part 30 is arranged in a housing 91 of the PC 90. The IC part 30 is mounted on a module board mounted on the main board 32. A thermal diffusion plate to which a heat sink, which is not shown, is thermally connected is connected to one of the main surfaces of the IC part 30, which is to be cooled. The thermoelectric devices 10 are embedded in this thermal diffusion plate.

Embodiments of the present invention are not limited to the above-described embodiments and various other embodiments may be included.

For example, the p-type thermoelectric elements 11p and the n-type thermoelectric elements 11n are partially insulated from each other by the first insulators 12 and certain p-type thermoelectric elements 11p are directly connected to certain n-type thermoelectric elements 11n by pn junctions in the above-described embodiments. However, embodiments of the present invention are not limited thereto. Grooves may be formed between the p-type thermoelectric elements 11p and the n-type thermoelectric elements 11n by deep reactive-ion etching (DRIE) in such a manner that part of the p-type thermoelectric elements 11p are connected to part of the n-type thermoelectric elements 11n without the first insulators 12. An oxide film may be formed on the surface of these grooves, or no special processing may be performed. This structure can partially insulate the p-type thermoelectric elements 11p from the n-type thermoelectric elements 11n by air layers in the grooves.

A desktop PC has been mentioned as an example of the electronic appliance. However, embodiments of the present invention are not limited thereto. Examples of the electronic appliance include personal digital assistants (PDAs), electronic dictionaries, cameras, display devices, audio/visual devices, projectors, cell phones, game machines, car navigation devices, robots, laser generators, and other electronic products.

The present application contains subject matter related to that disclosed in Japanese Priority Patent Application JP 2009-098547 filed in the Japan Patent Office on Apr. 15, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A thermoelectric device comprising:
rows of thermoelectric elements, each of which includes a plurality of p-type thermoelectric elements and a plurality of n-type thermoelectric elements that are alternately arranged in a first direction, the n-type thermoelectric elements each having a junction area electrically connected to one of the p-type thermoelectric elements that adjoins the n-type thermoelectric element;
first insulators; and
a second insulator,
wherein the first insulators are each arranged between a corresponding one of the p-type thermoelectric elements and one of the n-type thermoelectric elements that adjoins the p-type thermoelectric element,
the rows of the thermoelectric elements are arranged in a second direction perpendicular to the first direction and connected to each other, and
the second insulator is arranged between the rows of thermoelectric elements in such a manner that the p-type thermoelectric elements and n-type thermoelectric elements of the rows of the thermoelectric elements are electrically connected in series.

2. The thermoelectric device according to claim 1,
wherein, in each row of the thermoelectric elements, each of the p-type thermoelectric elements is electrically connected to one of the n-type thermoelectric elements that adjoins the p-type thermoelectric element so as to form a pi junction.

3. The thermoelectric device according to claim 2,
wherein a p-type thermoelectric element located in the first direction at one end of one of the rows of the thermoelectric elements is electrically connected to an n-type thermoelectric element located in the first direction at the same end of an adjoining one of the rows of the thermoelectric elements.

4. A manufacturing method for manufacturing a thermoelectric device, comprising the steps of:
obtaining a first layered product by alternately stacking a plurality of p-type thermoelectric elements and a plurality of n-type thermoelectric elements in a first direction and by arranging first insulators each between a corresponding one of the p-type thermoelectric elements and one of the n-type thermoelectric elements that adjoins the p-type thermoelectric element in such a manner that the p-type thermoelectric elements and the n-type thermoelectric elements are electrically connected to each other at junction areas;
obtaining a connected product by connecting the stacked p-type and n-type thermoelectric elements of the first layered product to each other through pressing the first layered product while heating;
obtaining rows of thermoelectric elements by cutting the connected product, each of which is constituted by the p-type thermoelectric elements and the n-type thermoelectric elements that are connected to each other;
obtaining a second layered product by stacking the rows of the thermoelectric elements and by arranging a second insulator between the rows of the thermoelectric elements in such a manner that the p-type thermoelectric elements and n-type thermoelectric elements of the rows of the thermoelectric elements are electrically connected in series; and
connecting the stacked rows of the thermoelectric elements of the second layer product to each other through pressing the second layered product while heating.

5. The manufacturing method according to claim 4,
wherein when the second layered product is obtained, in each row of the thermoelectric elements, each of the p-type thermoelectric elements is electrically connected to one of the n-type thermoelectric elements that adjoins the p-type thermoelectric element to form a pi junction.

6. The manufacturing method according to claim 5,
wherein when the second layered product is obtained, a p-type thermoelectric element located in the first direction at one end of one of the rows of the thermoelectric elements is electrically connected to an n-type thermoelectric element located in the first direction at the same end of an adjoining one of the rows of the thermoelectric elements.

7. A control system for controlling a thermoelectric device that includes
rows of thermoelectric elements, each of which includes a plurality of p-type thermoelectric elements and a plurality of n-type thermoelectric elements that are alternately arranged in a first direction, the n-type thermoelectric elements each having a junction area electrically connected to one of the p-type thermoelectric elements that adjoins the n-type thermoelectric element,
first insulators, and
a second insulator,
wherein the first insulators are each arranged between a corresponding one of the p-type thermoelectric elements and one of the n-type thermoelectric elements that adjoins the p-type thermoelectric element,
the rows of the thermoelectric elements are arranged in a second direction perpendicular to the first direction and connected to each other, and
the second insulator is arranged between the rows of thermoelectric elements in such a manner that the p-type thermoelectric elements and n-type thermoelectric elements of the rows of the thermoelectric elements are electrically connected in series, the control system comprising:
an input unit that receives temperature information regarding an integrated circuit part to be cooled; and
a control circuit that controls a current to be supplied to the thermoelectric device in accordance with the temperature information received by the input unit.

8. The control system according to claim 7,
wherein the thermoelectric device is one of thermoelectric devices to be controlled by the control system, the integrated circuit part is one of integrated circuit parts to be cooled, and the thermoelectric devices are arranged with respect to the integrated circuit parts,
the input unit receives temperature information regarding each of the integrated circuit parts to be cooled, and
the control circuit individually controls currents to be supplied to the thermoelectric devices in accordance with the temperature information received by the input unit.

9. An electronic appliance comprising:
a heat source that has a package; and
a thermoelectric device provided at the package of the heat source, the thermoelectric device including
rows of thermoelectric elements, each of which includes a plurality of p-type thermoelectric elements and a plurality of n-type thermoelectric elements that are alternately arranged in a first direction, the n-type thermoelectric elements each having a junction area electrically connected to one of the p-type thermoelectric elements that adjoins the n-type thermoelectric element,
first insulators, and
a second insulator,
wherein the first insulators are each arranged between a corresponding one of the p-type thermoelectric elements and one of the n-type thermoelectric elements that adjoins the p-type thermoelectric element,
the rows of the thermoelectric elements are arranged in a second direction perpendicular to the first direction and connected to each other, and
the second insulator is arranged between the rows of thermoelectric elements in such a manner that the p-type thermoelectric elements and n-type thermoelectric elements of the rows of the thermoelectric elements are electrically connected in series.
